(19) United States
(12) Patent Application Publication
(10) Pub. No.: US 2007/0137891 A1
(43) Pub. Date: Jun. 21, 2007

(54) PASSING MULTIPLE CONDUCTIVE TRACES THROUGH A THRU-HOLE VIA IN A PCB

(76) Inventors: Jun Fan, San Marcos, CA (US); Arthur Ray Alexander, Valley Center, CA (US); James Knighten, Poway, CA (US); Norman Smith, San Marcos, CA (US); Joseph Fleming, San Diego, CA (US)

Correspondence Address: John D. Cowart;Intellectual Property Section, Law Department, NCR Corporation, 1700 South Patterson Blvd., Dayton, OH, 45479-0001, US

(21) Appl. No.: 11/563,820

(22) Filed: Nov. 28, 2006

Related U.S. Application Data
(60) Provisional application No. 60/752,581, filed on Dec. 21, 2005.

(51) Int. Cl. H05K 1/11; H01R 12/04

(52) U.S. Cl. 174/262; 174/260

(57) ABSTRACT

A printed circuit board has one or more layers on which electrically conductive traces reside. The printed circuit board also includes a thru-hole via formed in one or more of the layers. The thru-hole via includes at least two electrically conductive portions that are electrically isolated from each other, where the electrically conductive portions connect electrically to separate conductive traces.

### CROSS-REFERENCE TO RELATED APPLICATIONS

This application claims priority from U.S. Provisional Application 60/752,581, filed on Dec. 21, 2005, by Jun Fan, Arthur R. Alexander, James L. Knighten, Norman W. Smith and Joseph Fleming. This application is related to U.S. application Ser. No. ______, titled “Using a Thru-Hole Via to Improve Circuit Density in a PCB,” and filed on ______, by James L. Knighten, Jun Fan and Norman W. Smith (NCR matter 12336); and to U.S. application Ser. No. ______, titled “Crossing Conductive Traces in a PCB,” and filed on ______, by James L. Knighten, Norman W. Smith and Jun Fan (NCR matter 12366).

### BACKGROUND

Thru-hole vias are used routinely in multi-layer printed circuit boards (PCBs) to allow signal traces to extend from one layer to another in the PCB. As data rates in PCBs increase and the rise-and-fall times of digital signals decrease, thru-hole vias are becoming one of the major contributors to many signal integrity and EMI problems in PCBs. Each thru-hole via that carries a signal trace and that appears in a PCB without an accompanying ground via (i.e., a via that provides a path for signal return current to flow back to its source) can easily degrade signal integrity and generate power-bus noise. However, providing a ground via for every signal via consumes precious PCB real estate, reducing the density at which the PCB can be populated, and thus reducing the PCB's effectiveness and driving up cost.

### SUMMARY

Described below is a printed circuit board having one or more layers on which electrically conductive traces reside. The printed circuit board also includes a thru-hole via formed in one or more of the layers. The thru-hole via includes at least two electrically conductive portions that are electrically isolated from each other, where the electrically conductive portions connect electrically to separate conductive traces.

The printed circuit board often includes two or more mounting pads positioned for mounting a single circuit component, where one of the mounting pads connects electrically to one of the electrically conductive portions of the thru-hole via, and where another of the mounting pads connects electrically to another of the electrically conductive portions of the thru-hole via. In some cases, two of the mounting pads are positioned on opposite sides of the thru-hole via. In these cases, the mounting pads are often positioned on one surface of the printed circuit board, while the electrically conductive traces to which the electrically conductive portions of the thru-hole via connect the mounting pads reside on another surface of the board.

The printed circuit board also often includes multiple layers, and in some cases the thru-hole via penetrates all of the layers.

Also described is a printed circuit board that includes multiple layers, including one or more reference-voltage layers and one or more layers on which electrically conductive traces reside. The printed circuit board also includes a thru-hole via having at least two electrically conductive portions that are electrically isolated from each other, where one of the electrically conductive portions connects electrically to one of the reference-voltage layers, and where another of the electrically conductive portions connects electrically to one of the electrically conductive traces.

The printed circuit board often includes at least two mounting pads positioned for mounting a single circuit component, where one of the mounting pads connects electrically to one of the electrically conductive portions of the thru-hole via, and where another of the mounting pads connects electrically to another of the electrically conductive portions of the thru-hole via. In some cases, two of the mounting pads are positioned on opposite sides of the thru-hole via. In these cases, the mounting pads are often positioned on one surface of the printed circuit board, while the electrically conductive trace to which the one mounting pad is connected electrically resides on another surface of the board.

Other features and advantages will become apparent from the description and claims that follow.

### BRIEF DESCRIPTION OF THE DRAWINGS

FIG. 1 is diagram showing a printed circuit board (PCB) with a thru-hole via through which multiple electrically conductive traces pass.

FIG. 2 is a diagram showing a cross-sectional view of a PCB having a thru-hole through which multiple traces pass.

FIGS. 3A, 3B, 3C, 3D and 3E together illustrate a process for forming a thru-hole via like that shown in FIG. 1 in a PCB.

FIGS. 4A and 4B are diagrams illustrating traditional techniques for routing traces from one layer of a PCB to a component on another layer of the PCB.

FIG. 5 is a diagram showing a technique for routing traces from one layer of a PCB to a component on another layer of the PCB using a thru-hole via like that shown in FIG. 1.

FIG. 6 is a diagram showing a pad footprint for a component that receives traces routed in the manner show in FIG. 5.

### DETAILED DESCRIPTION

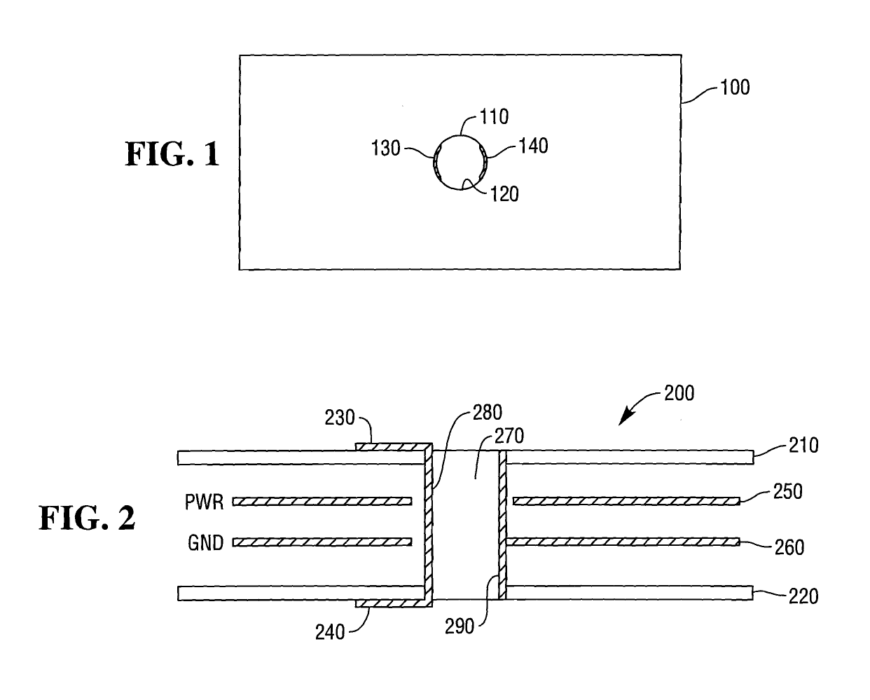

FIG. 1 shows a multi-layer printed circuit board (PCB) 100 having a thru-hole via 110 that is constructed to allow multiple conductive traces to pass from one layer of the PCB to another layer of the PCB. A thru-hole via or plated through hole, as the term is commonly understood in the art of PCB manufacturing, is a hole formed through the layers of a printed circuit board and then coated (or “plated”) with an electrically conductive material (typically a metal such as copper) to allow an electrical signal in the PCB to move from one layer to another and/or to allow a conductive pin on an electronic component to connect to a reference plane or a signal trace in the PCB. In a traditional thru-hole via, the conductive coating covers the entire surface of the via, thus allowing only a single conductive trace to pass through the via or a single electronic component to connect to the via.

The thru-hole via 110 of FIG. 1 is constructed so that its internal surface 120 includes multiple conductive portions 130, 140 that are separated physically by gaps. This ensures that the conductive portions 130, 140 are electrically isolated—i.e, that no electrically conductive path exists between the conductive portions 130, 140 when the PCB is fabricated and has not yet been populated with electronic components.

FIG. 2 shows one example of how a thru-hole via like that of FIG. 1 is often used to route traces through the layers of a multi-layer PCB 200. In this example, the PCB 200 includes at least two non-conductive substrate layers 210, 220 on which conductive signal traces 230, 240 are formed. The PCB 200 also includes at least two reference voltage layers 250, 260 (such as power and ground layers), which are electrically conductive layers (usually conductive planes) that typically are formed between the non-conductive substrate layers 210, 220. The thru-hole via 270 shown here is plated with two electrically isolated, electrically conductive portions 280, 290, which typically extend the entire length of the thru-hole via 270 (i.e., extend from one end of the via to the other). In this example, one of the conductive portions 280 connects the signal traces 230, 240 on the non-conductive substrate layers 210, 200 to each other, while the other conductive portion 290 connects one of the reference voltage layers 260 (e.g., a ground layer) to components (not shown) residing on one or both of the non-conductive substrate layers 210, 200. The result is that a single thru-hole via 270 is used to pass multiple traces through the layers of the PCB 200. In the example shown here, those traces are a signal trace and a reference-voltage trace, but thru-hole vias like the one shown here are also used to pass, e.g., multiple signal traces or multiple reference-voltage traces.

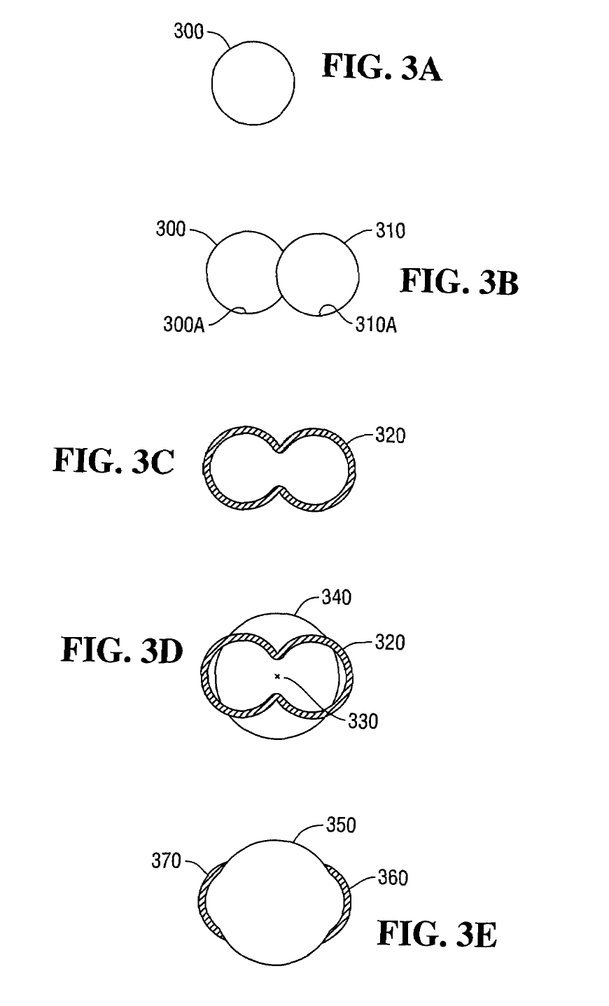

FIGS. 3A, 3B, 3C, 3D and 3E show a process for forming a thru-hole like that shown in FIGS. 1 and 2 in a printed circuit board. The process begins by forming a single hole 300 (FIG. 3E) through some or all of the layers of the PCB, typically by passing the bit of a PCB drill through the PCB. A second hole 310 (FIG. 3B) is then formed in the PCB by passing the bit of the PCB drill through PCB again, this time in a position that is different than that used to form the first hole 300 intersects but that allows the second hole 310 to intersect the first hole 300.

After two passes of the PCB drill have formed intersecting holes in the PCB, the inner surfaces 300A, 310A of the holes 300, 310 are coated with an electrically conductive material 320 (FIG. 3C). In most PCBs, the electrically conductive material 320 coats the inner surfaces 300A, 310B of the holes 300, 310 in their entirety, extending along the entire lengths of the holes 300, 310.

Once the inner surfaces 300A, 310A of the intersecting holes 300, 310 have been coated with the electrically conductive material 320, the PCB drill is passed through the PCB a third time, typically with a bit larger than that used to form the two intersecting holes 300, 310. For this pass, the PCB drill is positioned so that the bit passes very near the geometric center 330 (FIG. 3D) of the intersecting holes 300, 310, forming a third hole 340 that intersects both of the other holes 300, 310.

As the drill bit passes through the PCB on this pass, it carries away with it all of the electrically conductive material 320 that lies within its path, severing the electrical continuity that previously existed along the inner surfaces 300A, 310A of the intersecting holes 300, 310. The result is a single thru-hole via 350 that includes two electrically isolated, electrically conductive portions 360, 370 (FIG. 3E).

One use for which the thru-hole via described above is particularly suited is in routing signal traces, such as those carrying digital clocking signals, from one layer of a multi-layer PCB to another layer of the PCB. In particular, the thru-hole via described above is useful in reducing, or eliminating altogether, electromagnetic radiation that forms in the PCB and then exits the PCB in the form of electromagnetic interference (EMI).

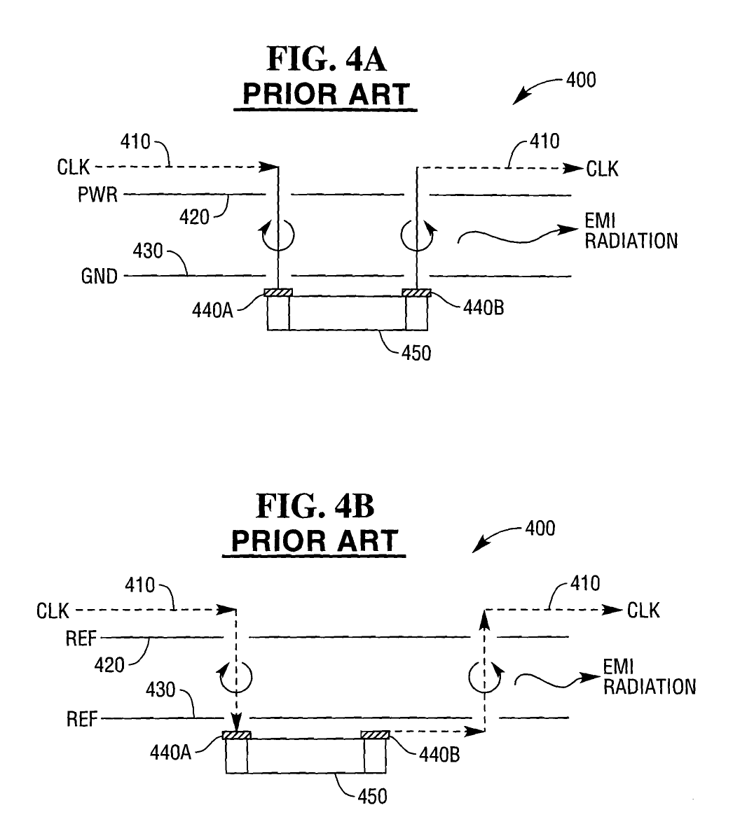

FIGS. 4A and 4B show two traditional techniques for routing signal traces through the layers of a multi-layer PCB 400. In the first of these techniques (FIG. 4A), the PCB 400 includes a clocking signal 410 that moves from one layer of the PCB to another layer, passing through one or more other layers of the PCB—including, for example, a power layer 420 and a ground layer 430. In this example, the clocking signal 410, after passing through the PCB 400, connects to one of the conductive mounting pads 440A associated with an electronic component 450 (e.g., a surface-mount resistor) that is mounted on a surface of the PCB 400. The clocking signal 410 then exits another of the mounting pads 440B associated with the component and passes immediately back through the layers of the PCB 400 to another surface of the PCB 400, typically the surface on which it originated.

This traditional approach to signal routing is known to created EMI problems in the PCBs in which it is used. The EMI originates in the portions of the clocking signal 410 that extend vertically through the layers of the PCB 400. The current carried in these portions of the clocking signal 410 generates magnetic fields that are shown by the circular arrows in FIG. 4A. Because the current moves in opposite directions in these portions of the clocking signal, these magnetic fields have opposite polarities and largely cancel each other out. However, because the magnetic fields at their origins are separated by some distance (e.g., the length of the electronic component 450 in this example), they do not cancel each other entirely, and electromagnetic radiation results. Because this effect often occurs many times in a typical PCB, the resulting EMI can be significant.

In the second of the traditional signal-routing techniques (FIG. 4B), the clocking signal passes through the layers of the PCB 400 to one of the mounting pads 440A of the electronic component 450 and then, after exiting the other mounting pad 440B, extends along the surface of the PCB 400 for some distance before passing back through the layers of the PCB. In this example, because the portions of the clocking signal 410 at which it passes through the layers of the PCB 400 are separated by even greater distance, the extent to which the opposing magnetic fields cancel each other out is not as great as in the example of FIG. 4A. The result is even greater EMI emissions from the PCB 400.

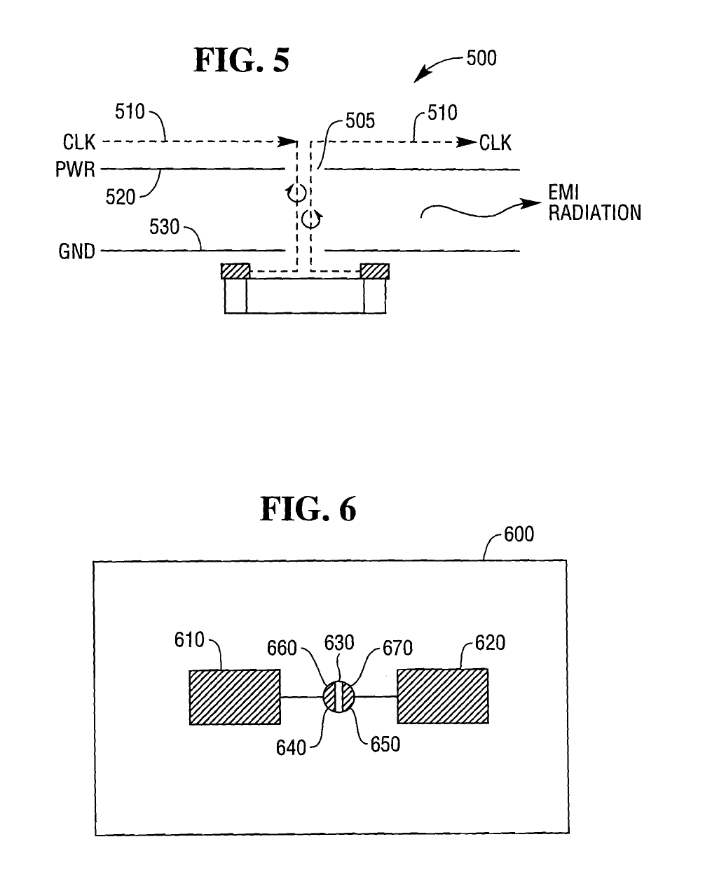

FIG. 5 shows a signal-routing technique in a PCB 500 that relies on a thru-hole via 505 like that described above to reduce, or even eliminate completely, resulting EMI. The PCB 500 shown here includes a clocking signal 510 that moves from one surface of the PCB 500 to another surface, passing through one or more layers of the PCB 500, such as a power layer 520 and a ground layer 530, along the way. In doing so, the clocking signal 510 moves along an electrically conductive portion of the thru-hole via 505.

After passing through the layers of the PCB, the clocking signal 510 extends along the surface of the PCB for a short distance toward one of the mounting pads 540A of a electronic component 550 (e.g., a surface-mount resistor or capacitor) mounted on the PCB. The clocking signal exits another mounting pad 540B of the electronic component 550 and extends along the surface of the PCB for a short distance back toward the thru-hole via 505. The clocking signal 510 then passes back through the layers of the PCB, moving along another electrically conductive portion of the thru-hole via 505, electrically isolated from the first.

As the clocking signal 510 passes through the thru-hole via 505 in opposite directions, along the two electrically isolated, electrically conductive portions of the thru-hole via 505, the current in the signal forms magnetic fields with opposite polarities. Unlike with traditional signal routing techniques, however, the magnetic fields formed in this example originate in such close proximity to each other (within the thru-hole via 505) that they cancel each other out almost entirely, if not entirely. The result is that very little, if any, EMI is attributable to the clocking signal 510 that passes through the thru-hole via 505.

FIG. 6 shows a sample mounting-pad footprint for use in mounting an electronic component to a multi-layered PCB 600 that uses a signal-routing technique like that shown in FIG. 5. For simple electronic component like a surface-mount resistor or capacitor that requires only two electrically conductive mounting pads, the PCB 600 includes two such pads 610, 620 positioned on opposite sides of a thru-hole via 630. As described above, the thru-hole via 630 includes multiple (in this case two) electrically isolated, electrically conductive portions 640, 650 that extend through some of all of the layers of the PCB 600. Electrically conductive traces 660, 670 extend across the surface of the PCB 600 to connect each of the mounting-pads 610, 620 to one of the electrically conductive portions 640, 650 of the thru-hole via 630.

With this component-mounting arrangement, an electrical signal carried by one of the electrically conductive portions 640 of the thru-hole via 630 enters a component that is mounted to the PCB 600 through the corresponding mounting pad 610. The signal exits the component through the other mounting pad 620 and is carried back through the layers of the PCB 600 by the other electrically conductive portion 650 of the thru-hole via 630.

The text above describes one or more specific embodiments of a broader invention. The invention also is carried out in a variety of alternative embodiments and thus is not limited to those described here. For example, each of the figures shows a thru-hole via through which two electrically conductive traces pass. In some systems, however, more than two electrically conductive traces will pass through some thru-hole vias. Likewise, while the thru-hole vias shown in the figures here are generally circular in shape, thru-hole vias of virtually any shape are useful as well.

Also, while the description above shows one way to fabricate such a thru-hole via, other fabrication techniques are suitable as well. For example, one such technique involves drilling a hole in the PCB and then plating a first electrically conductive portion on the surface of the thru-hole via while the rest of the surface is covered with an insulating material. A second electrically conductive portion is then plated on the surface of the via after the insulating material had been removed from the via and reapplied elsewhere in the via, leaving exposed only that area on which the second electrically conductive portion is to be plated. The plated via is complete after the insulating material is removed from the surface of the via a second time.

Another fabrication technique involves plating the entire surface of the thru-hole via with an electrically conductive material and then using a tool, such as a high power laser, to remove some portion of the conductive material from the surface of the via. With this technique, the conductive material is removed in a manner that creates electrical isolation between conductive surfaces in the thru-hole via. Many other embodiments are also within the scope of the following claims.

We claim:

1. A printed circuit board comprising:
one or more layers on which electrically conductive traces reside; and
a thru-hole via formed in one or more of the layers;
where the thru-hole via includes at least two electrically conductive portions that are electrically isolated from each other; and
where the electrically conductive portions of the thru-hole via connect electrically to separate conductive traces.

2. The printed circuit board of claim 1, further comprising two or more mounting pads positioned for mounting a single circuit component, where one of the mounting pads connects electrically to one of the electrically conductive portions of the thru-hole via, and where another of the mounting pads connects electrically to another of the electrically conductive portions of the thru-hole via.

3. The printed circuit board of claim 2, where two of the mounting pads are positioned on opposite sides of the thru-hole via.

4. The printed circuit board of claim 2, where the mounting pads are positioned on one surface of the printed circuit board, and where the electrically conductive traces to which the electrically conductive portions of the thru-hole via connect the mounting pads reside on another surface of the board.

5. The printed circuit board of claim 1, where the printed circuit board includes multiple layers.

6. The printed circuit board of claim 5, where the thru-hole via penetrates all of the layers.

7. A printed circuit board comprising:
multiple layers, including one or more reference-voltage layers and one or more layers on which electrically conductive traces reside; and
a thru-hole via having at least two electrically conductive portions that are electrically isolated from each other,
where one of the electrically conductive portions connects electrically to one of the reference-voltage layers; and
where the another of the electrically conductive portions connects electrically to one of the electrically conductive traces.

8. The printed circuit board of claim 7, further comprising at least two mounting pads positioned for mounting a single circuit component, where one of the mounting pads connects electrically to one of the electrically conductive portions of the thru-hole via, and where another of the mounting pads connects electrically to another of the electrically conductive portions of the thru-hole via.

9. The printed circuit board of claim 8, where two of the mounting pads are positioned on opposite sides of the thru-hole via.

10. The printed circuit board of claim 8, where the mounting pads are positioned on one surface of the printed circuit board, and where the electrically conductive trace to which the one mounting pad is connected electrically resides on another surface of the board.

11. The printed circuit board of claim 7, where the thru-hole via penetrates all layers of the printed circuit board.

12. A method for use in manufacturing a printed circuit board, the method comprising:
drilling a first hole in the printed circuit board;
drilling a second hole in the printed circuit board in a position that intersects the first hole;
applying an electrically conductive material inside the first and second holes; and then
drilling a third hole in the printed circuit board in a position that intersects both the first and second holes to form a thru-hole via with two electrically conductive portions that are electrically isolated from each other.

13. The method of claim 12, where the printed circuit board includes multiple layers, and where drilling the first, second and third holes includes drilling the holes to penetrate all layers of the printed circuit board.

14. The method of claim 12, further comprising forming on the circuit board at least two mounting pads positioned for mounting a single electronic component, such that one of the mounting pads connects electrically to one of the electrically conductive portions of the thru-hole via and another of the mounting pads connects electrically to the other electrically conductive portion of the thru-hole via.

15. The method of claim 12, further comprising forming electrically conductive traces on the printed circuit board, such that each of the electrically conductive portions of the thru-hole via connects to at least one of the electrically conductive traces.
